(19) United States
(12) Patent Application Publication
(10) Pub. No.: US 2009/0213891 A1
(43) Pub. Date: Aug. 27, 2009

(54) SEMICONDUCTOR LASER

(75) Inventors: Yasuyuki Nakagawa, Tokyo (JP); Kyosuke Kuramoto, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 12/352,623

(22) Filed: Jan. 13, 2009

(30) Foreign Application Priority Data
Jan. 22, 2008 (JP) 2008-011439

(51) Int. Cl. H01S 5/028

(52) U.S. Cl. 372/49.01

(57) ABSTRACT

A GaN semiconductor laser, includes a coating film on a front end surface through which laser light is emitted. The coating film includes a first insulating film in contact with the front end surface and a second insulating film on the first insulating film. The sum of the optical film thicknesses of the first insulating film and the second insulating film is an odd multiple of λ/4 with respect to the wavelength λ of laser light produced by the semiconductor laser. The adhesion of the first insulating film to GaN is stronger than that of the second insulating film to GaN. The refractive index of the first insulating film is 1.9 or less and the refractive index of the second insulating film is 2 to 2.3.

### BACKGROUND OF THE INVENTION

1. Field of the Invention

The present invention relates to a GaN semiconductor laser having a coating film formed on a front end surface through which laser light is emitted and, more particularly, to a semiconductor laser in which the reflectance of a coating film is set in the range from 3 to 13%, and which is capable of preventing separation of the coating film and being reliable.

2. Background Art

Semiconductor lasers are being widely used in optical disk systems, optical communication, etc. In recent years, GaN semiconductor lasers which emit blue laser light have been put to use. A semiconductor laser has a front end surface through which laser light is emitted and a rear end surface opposed to the front end surface. Coating films are formed on the front end surface and the rear end surface to achieve, for example, a reduction in the operating current for the semiconductor laser, prevention of return light and an increase in output.

A semiconductor laser required to have an increased output ordinarily has a coating film of a low reflectance formed on the front end surface and a coating film of a high reflectance formed on the rear end surface. The reflectance of the coating film on the rear end surface is ordinarily 60% or more, preferably 80% or more. On the other hand, it is not sufficient to simply lower the reflectance of the coating film on the front end surface. The reflectance at the front end surface is set according to a characteristic required of the semiconductor laser. For example, a reflectance of about 0.01 to 3% is set in a fiber amplifier excitation semiconductor laser used with a fiber grating; a reflectance of about 3 to 7% in an ordinary high-output semiconductor laser; and a reflectance of about 7 to 13% in a case where there is a need to take a measure against return light.

FIG. 9 is a diagram showing a film thickness dependence of the reflectance of a coating film using a single layer of Al₂O₃ film. For example, in a case where the film thickness of Al₂O₃ film is set to 91.5 nm in order to set the reflectance to about 10%, the actual reflectance is 9.91%; the reflectance can be set within the target range from 3 to 13%. In this case, if the film thickness of Al₂O₃ film varies by ±5%, the reflectance varies largely between the minimum 7.72 and the maximum 12.03%. To narrow this reflectance variation, the film thickness may be set in the vicinity of an inflection point of the reflectance. In the case of Al₂O₃ film, however, the reflectance at the inflection point is 1% or less, out of the range from 3 to 13%.

FIG. 10 is a diagram showing a film thickness dependence of the reflectance of a coating film using a single layer of Ta₂O₅ film. In the case of Ta₂O₅ film, the reflectance at an inflection point is about 10%. Therefore, if a single layer of Ta₂O₅ film is used as coating film on the front end surface, the reflectance can be set within the range from 3 to 13% while narrowing variation in the reflectance.

A technique using a two-layer film as coating film has also been proposed (see, for example, Japanese Patent Laid-Open No. 2000-22269).

### SUMMARY OF THE INVENTION

Because Ta₂O₅ film has low adhesion to a GaN substrate, there was a problem that if a single layer of Ta₂O₅ film is used as coating film, separation of the coating film occurs. Japanese Patent Laid-Open No. 2000-22269 contains no description of a combination of two layers of films in which the film in contact with a GaN substrate has good adhesion to the GaN substrate, and the reflectance of which is set in the range from 3 to 13%.

FIG. 11 is a set of diagrams showing a wavelength dependence of the reflectance of a coating film formed of a single layer of Al₂O₃ film on a front end surface of a GaN semiconductor laser and an electric field distribution in the vicinity of the interface between the coating film and the GaN semiconductor laser. The Al₂O₃ film has a film thickness of 90 nm and a reflectance of 9.3%. It can be understood from these diagrams that the field intensity is high at the interface between the semiconductor laser and the coating film. Therefore, the crystal in the vicinity of the interface deteriorates and the reliability of the semiconductor laser is impaired.

Each of FIGS. 12 and 13 is a set of diagrams showing a wavelength dependence of the reflectance of a coating layer formed of a two-layer film consisting of Al₂O₃ film and Ta₂O₅ film on a front end surface of a GaAs semiconductor laser and an electric field distribution in the vicinity of the interface between the coating film and the GaAs semiconductor laser. Referring to FIG. 12, the Al₂O₃ film has a film thickness of 200 nm, the Ta₂O₅ film has a film thickness of 78 nm, and the reflectance is 0.66%. Referring to FIG. 13, the Al₂O₃ film has a film thickness of 250 nm, the Ta₂O₅ film has a film thickness of 30 nm, and the reflectance is 0.49%. FIG. 14 is a set of diagrams showing a wavelength dependence of the reflectance of a coating film formed of a two-layer film consisting of Si₃N₄ film and SiO₂ film on a front end surface of a GaAs semiconductor laser, and an electric field distribution in the vicinity of the interface between the coating film and the GaAs semiconductor laser. The Si₃N₄ film has a film thickness of 78.6 nm, the SiO₂ film has a film thickness of 220 nm, and the reflectance is 0.52%. It can be understood from these diagrams that in some case the field intensity is high at the interface between the semiconductor laser and the coating film. Therefore, the crystal in the vicinity of the interface deteriorates and the reliability of the semiconductor laser is impaired.

Also, since the refractive index of GaAs or InP is 3.5 or more, the reflectance of the coating film cannot be set within the range from 3 to 13% by adjusting the film thicknesses in the two-layer film in a GaAs or InP semiconductor laser.

In view of the above-described problems, an object of the present invention is to provide a semiconductor laser in which the reflectance of a coating film is set in the range from 3 to 13%, and which is capable of preventing separation of the coating film and being reliable.

According to one aspect of the present invention, a semiconductor laser formed as a GaN semiconductor laser, comprises a coating film formed on a front end surface through which laser light is emitted, the coating film having a first insulating film in contact with the front end surface and a second insulating film formed on the first insulating film, wherein the sum of the optical film thicknesses of the first insulating film and the second insulating film is an odd multiple of λ/4 with respect to the wavelength λ of laser light produced by the semiconductor laser; the adhesion of the first insulating film to GaN is stronger than that of the second insulating film; the refractive index of the first insulating film is 1.9 or less; and the refractive index of the second insulating film is 2 to 2.3.

According to the present invention, the reflectance of the coating film is set in the range from 3 to 13%, separation of the coating film can be prevented and the reliability of the semiconductor laser can be ensured.

Other and further objects, features and advantages of the invention will appear more fully from the following description.

### BRIEF DESCRIPTION OF THE DRAWINGS

FIG. 1 is a perspective view showing a semiconductor laser according to a first embodiment of the present invention.

FIG. 2 is a sectional view of the semiconductor laser.

FIGS. 3 to 6 are diagrams showing a wavelength dependence of the reflectance of the coating layer in the semiconductor laser according to the first embodiment of the present invention and an electric field distribution in the vicinity of the interface between the semiconductor laser and the coating layer.

FIG. 7 is a sectional view of a semiconductor laser according to a second embodiment of the present invention.

FIG. 8 is a set of diagrams showing a wavelength dependence of the reflectance of the coating film in the semiconductor laser according to the second embodiment of the present invention and an electric field distribution in the vicinity of the interface between the coating film and the semiconductor laser.

FIG. 9 is a diagram showing a film thickness dependence of the reflectance of a coating film using a single layer of Al₂O₃ film.

FIG. 10 is a diagram showing a film thickness dependence of the reflectance of a coating film using a single layer of Ta₂O₅ film.

FIG. 11 is a set of diagrams showing a wavelength dependence of the reflectance of a coating film formed of a single layer of Al₂O₃ film on a front end surface of a GaN semiconductor laser and an electric field distribution in the vicinity of the interface between the coating film and the GaN semiconductor laser.

FIGS. 12 and 13 are diagrams showing a wavelength dependence of the reflectance of a coating layer formed of a two-layer film consisting of Al₂O₃ film and Ta₂O₅ film on a front end surface of a GaAs semiconductor laser and an electric field distribution in the vicinity of the interface between the coating film and the GaAs semiconductor laser.

FIG. 14 is a set of diagrams showing a wavelength dependence of the reflectance of a coating film formed of a two-layer film consisting of Si₃N₄ film and SiO₂ film on a front end surface of a GaAs semiconductor laser, and an electric field distribution in the vicinity of the interface between the coating film and the GaAs semiconductor laser.

### DETAILED DESCRIPTION OF THE PREFERRED EMBODIMENTS

### First Embodiment

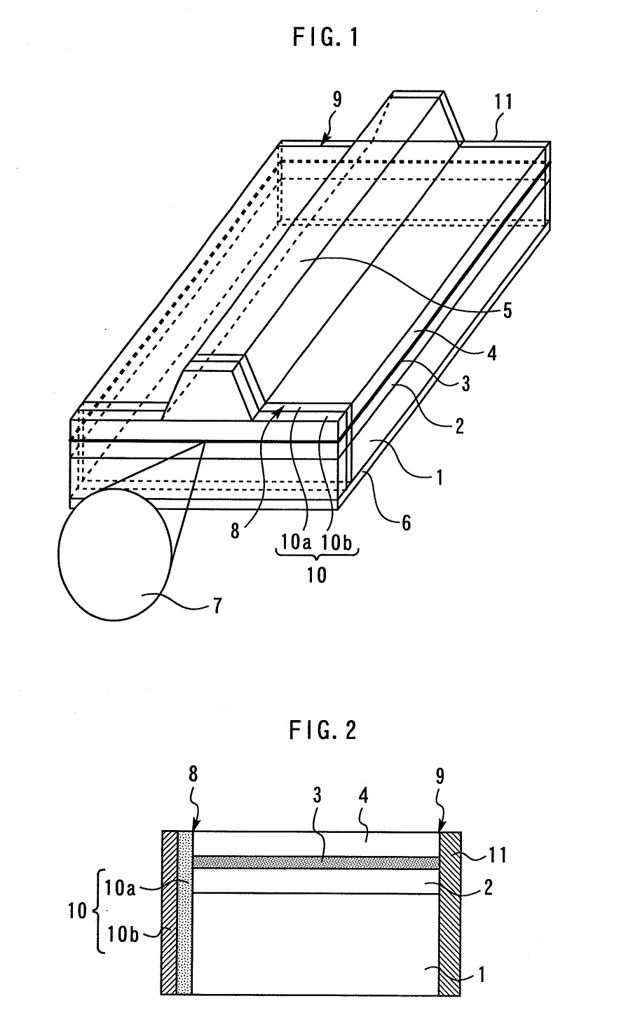

FIG. 1 is a perspective view showing a semiconductor laser according to a first embodiment of the present invention. FIG. 2 is a sectional view of the semiconductor laser. The semiconductor laser according to the first embodiment is a GaN semiconductor laser which emits blue laser light.

An n-clad layer 2, an active layer 3 and a p-clad layer 4 are formed in this order on a GaN substrate 1. A ridge-type p-electrode 5 is formed thereon. An n-electrode 6 is formed on the back surface of the GaN substrate 1. The GaN substrate 1, the n-clad layer 2, the active layer 3, the p-clad layer 4, the p-electrode 5 and the n-electrode 6 constitute a resonator along a direction in which laser light travels. One end of the resonator is a front end surface 8 through which laser light is emitted, and the other end of the resonator is a rear end surface 9.

When the above-described semiconductor laser is operated, a positive electric field is applied to the p-electrode 5 and a negative electric field is applied to the n-electrode 6. Positive holes and electrons are thereby injected into the active layer 3 from the p-clad layer 4 and the n-clad layer 2, respectively. These positive holes and electrons couple with each other to produce laser light 7 in the active layer 3. The laser light 7 travels in the active layer 3 along the resonator to be emitted from the front end surface 8 side.

A coating film 10 is formed on the front end surface 8, while a coating film 11 is formed on the rear end surface 9. The coating film 10 has Al₂O₃ film 10a (first insulating film) in contact with the front end surface 8, and Ta₂O₅ film 10b (second insulating film) formed on the Al₂O₃ film 10a. The Al₂O₃ film 10a and the Ta₂O₅ film 10b are formed, for example, by sputtering using electron cyclotron resonance or by chemical vapor deposition.

The coating film 11 is a multilayer film formed of SiO₂ film and Ta₂O₅ film for example. The coating film 11 has a high reflectance of about 90%, higher than that of the coating film 10. With this arrangement, the loss of laser light through the rear end surface 9 can be reduced. As a result, a high optical output of 50 mW or more can be obtained from the front end surface 8.

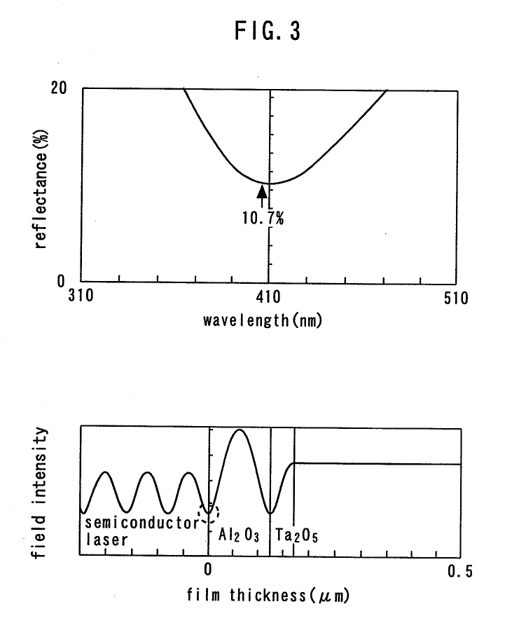

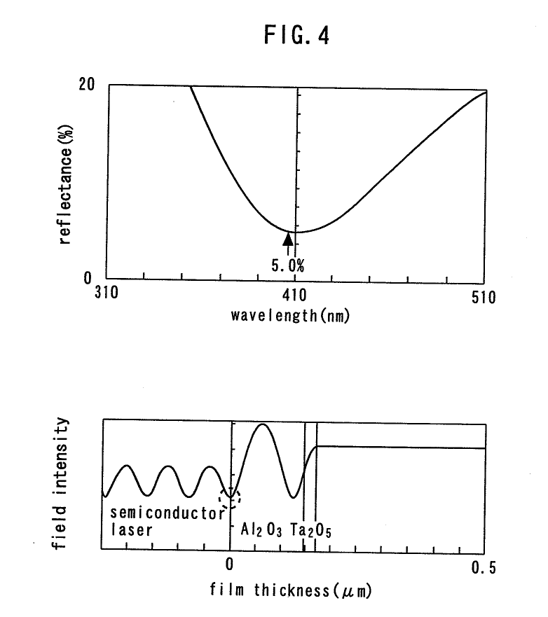

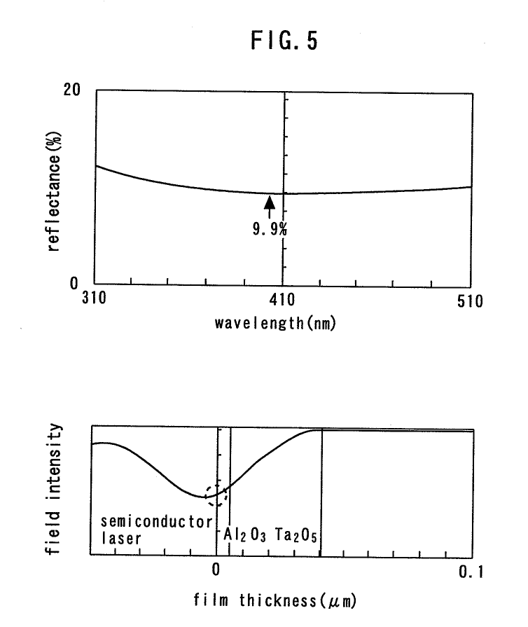

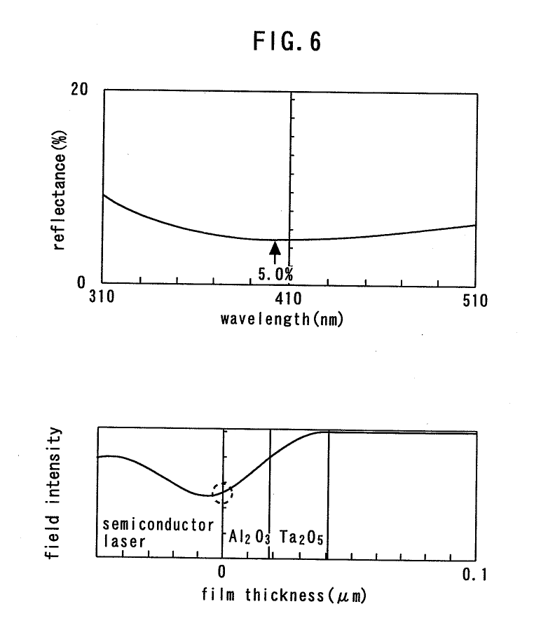

FIGS. 3 to 6 are diagrams showing a wavelength dependence of the reflectance of the coating layer in the semiconductor laser according to the first embodiment of the present invention and an electric field distribution in the vicinity of the interface between the semiconductor laser and the coating layer. Referring to FIG. 3, the Al₂O₃ film 10a is 123 nm thick, the Ta₂O₅ film 10b is 46 nm thick, and the reflectance is 10.7%. Referring to FIG. 4, the Al₂O₃ film 10a is 144.5 nm thick, the Ta₂O₅ film 10b is 23.5 nm thick, and the reflectance is 5.0%. Referring to FIG. 5, the Al₂O₃ film 10a is 5 nm thick, the Ta₂O₅ film 10b is 36 nm thick, and the reflectance is 9.9%. Referring to FIG. 6, the Al₂O₃ film 10a is 19 nm thick, the Ta₂O₅ film 10b is 22 nm thick, and the reflectance is 5.0%.

The sum of the optical film thicknesses of the Al₂O₃ film 10a and the Ta₂O₅ film 10b is λ/4×3 with respect to the wavelength λ of laser light produced by the semiconductor laser when the Al₂O₃ film 10a and the Ta₂O₅ film 10b have the film thicknesses shown in FIG. 3 or 4, and the sum of the optical film thicknesses of the Al₂O₃ film 10a and the Ta₂O₅ film 10b is λ/4 when the Al₂O₃ film 10a and the Ta₂O₅ film 10b have the film thicknesses shown in FIG. 5 or 6. The sum of the optical film thicknesses of the Al₂O₃ film 10a and the Ta₂O₅ film 10b is thus set to an odd multiple of λ/4 to reduce the field intensity at the interface between the semiconductor laser and the coating film 10. Deterioration of the crystal in the vicinity of the interface can be prevented in this way to ensure the reliability of the semiconductor laser.

The adhesion of the Al₂O₃ film 10a to the GaN is stronger than that of the Ta₂O₅ film 10b. Therefore, separation of the coating film 10 can be prevented.

The refractive index of the Al₂O₃ film 10a is 1.9 or less and the refractive index of the Ta₂O₅ film 106 is 2 to 2.3. Therefore, the reflectance of the coating film 10 can be set within the target range from 3 to 13% with respect to the GaN semiconductor laser by adjusting the film thickness of the Al₂O₃ film 10a and the film thickness of the Ta₂O₅ film 106.

The Al₂O₃ film 10a is an oxide film of a stoichiometric composition. Therefore, the amount of absorption of light by the Al₂O₃ film 10a is small, and deterioration of the crystal in the vicinity of the interface between the semiconductor laser and the coating film 10 can be prevented to ensure the reliability of the semiconductor laser.

SiO₂ film may be used in place of the Al₂O₃ film 10a. Also, a film formed of one of Nb₂O₅, HfO₂, ZrO₂, Y₂O₃, AlN and SiN may be used in place of the Ta₂O₅ film 10b.

### Second Embodiment

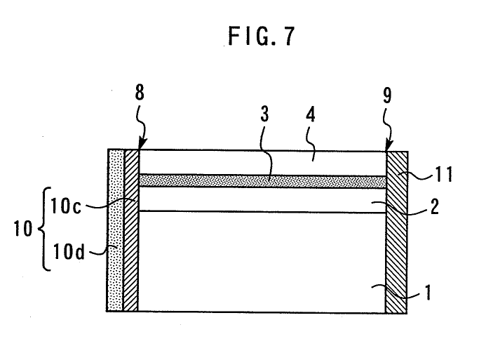

FIG. 7 is a sectional view of a semiconductor laser according to a second embodiment of the present invention. A coating film 10 has Si₃N₄ film 10c (first insulating film) in contact with the front end surface 8, and SiO₂ film 10d (second insulating film) formed on the Si₃N₄ film 10c. In other respects, the construction is the same as that in the first embodiment.

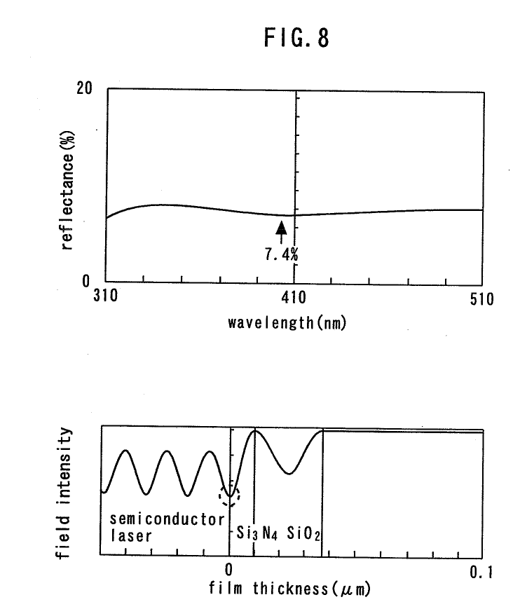

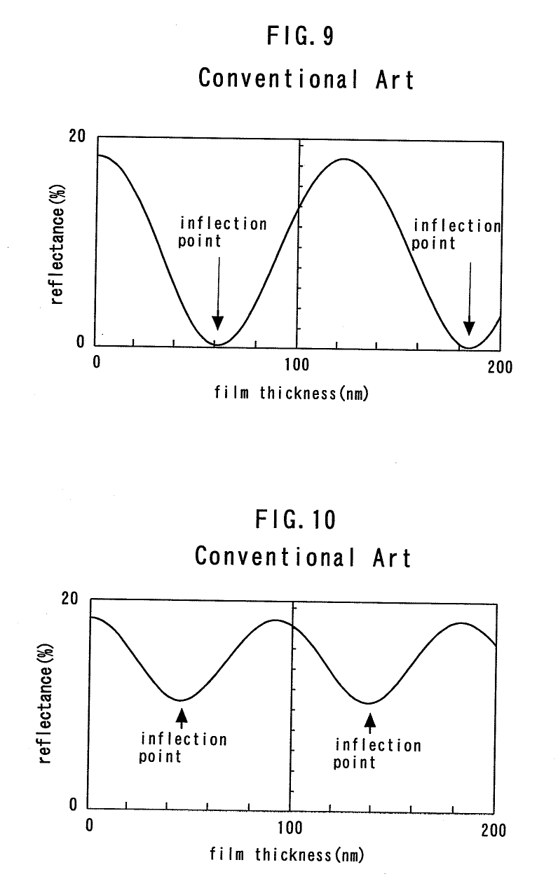

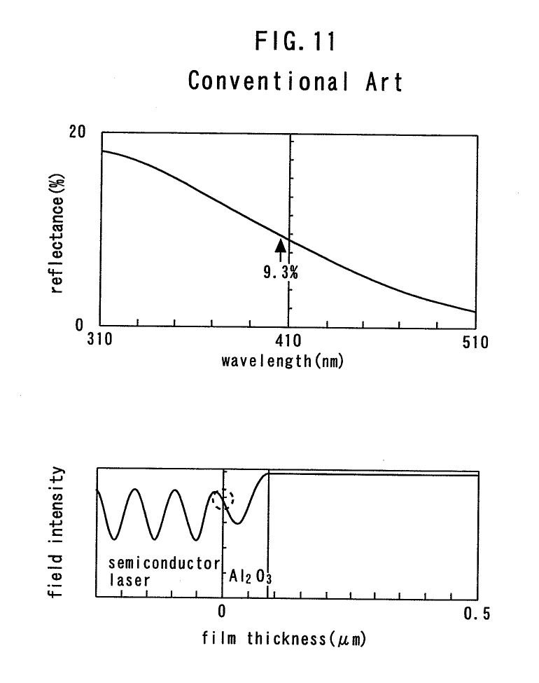

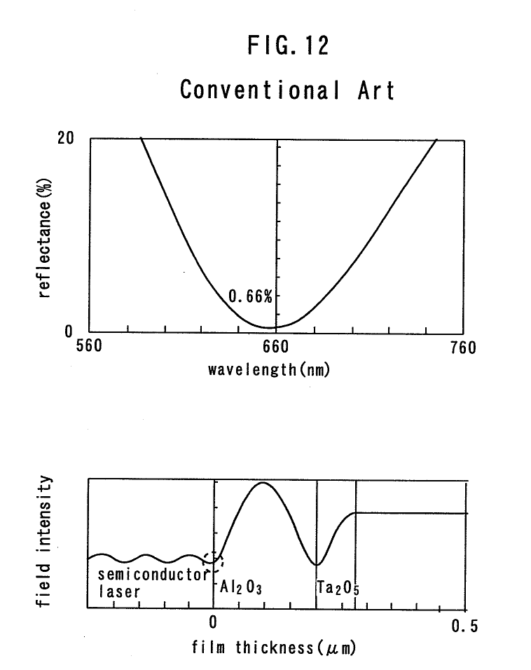

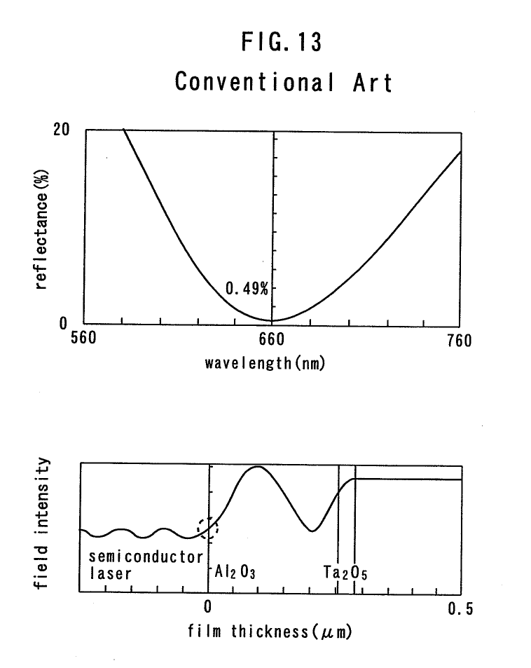

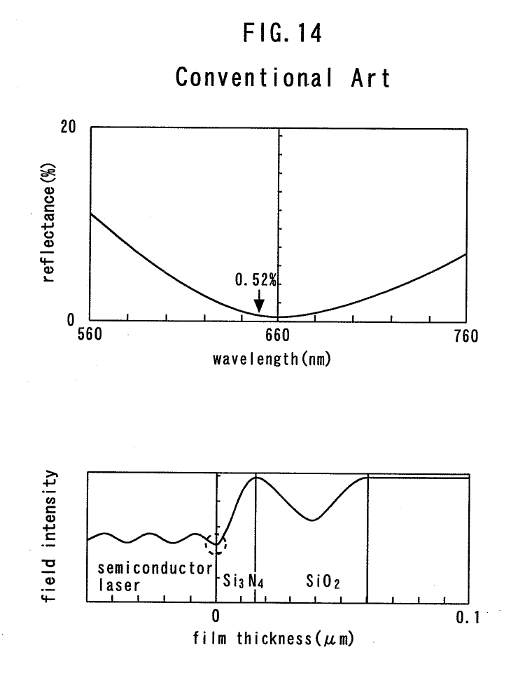

FIG. 8 is a set of diagrams showing a wavelength dependence of the reflectance of the coating film in the semiconductor laser according to the second embodiment of the present invention and an electric field distribution in the vicinity of the interface between the coating film and the semiconductor laser. The Si₃N₄ film 10c is 48.6 nm thick, the SiO₂ film 10d is 135.8 nm thick, and the reflectance is 7.4%. The sum of the optical film thicknesses of the Si₃N₄ film 100 and the SiO₂ film 10d is set to an odd multiple of λ/4 to reduce the field intensity at the interface between the semiconductor laser and the coating film 10. Deterioration of the crystal in the vicinity of the interface can be prevented in this way to ensure the reliability of the semiconductor laser.

The refractive index of the Si₃N₄ film 10c is 2 to 2.3 and the refractive index of the SiO₂ film 10d is 1.9 or less. Therefore, the reflectance of the coating film 10 can be set within the target range from 3 to 13% with respect to the GaN semiconductor laser by adjusting the film thickness of the Si₃N₄ film 10c and the film thickness of the SiO₂ film 10d.

The Si₃N₄ film 10c is a nitride film having strong adhesion to GaN. Therefore, separation of the coating film 10 can be prevented.

AlN film may be used in place of the Si₃N₄ film 10c. Also, Al₂O₃ film may be used in place of the SiO₂ film 10d. It is also possible to slightly change the refractive index by changing the composition ratio of Si and N in Si₃N₄ film 10c from the stoichiometric composition.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2008-011439, filed on Jan. 22, 2008 including specification, claims, drawings and summary, on which the Convention priority of the present application is based, are incorporated herein by reference in its entirety.

1. A GaN semiconductor laser, comprising:
a coating film on a front end surface through which laser light is emitted, the coating film including a first insulating film in contact with the front end surface and a second insulating film on the first insulating film, wherein
the sum of optical film thicknesses of the first insulating film and the second insulating film is an odd multiple of λ/4 with respect to the wavelength λ of laser light produced by the semiconductor laser,
adhesion of the first insulating film to GaN is stronger than that of the second insulating film to GaN,
refractive index of the first insulating film does not exceed 1.9, and
refractive index of the second insulating film is 2 to 2.3.

2. The semiconductor laser according to claim 1, wherein the first insulating film is an oxide film having a stoichiometric composition.

3. The semiconductor laser according to claim 1, wherein the first insulating film is Al₂O₃ or SiO₂.

4. The semiconductor laser according to claim 1, wherein the second insulating film is selected from the group consisting of Ta₂O₅, Nb₂O₅, HfO₂, ZrO₂, Y₂O₃, AlN, and SiN.

5. A GaN semiconductor laser, comprising:
a coating film on a front end surface through which laser light is emitted, the coating film including a first insulating film in contact with the front end surface and a second insulating film on the first insulating film, wherein
the sum of optical film thicknesses of the first insulating film and the second insulating film is an odd multiple of λ/4 with respect to the wavelength λ of laser light produced by the semiconductor laser,
the first insulating film is a nitride film,
refractive index of the first insulating film is 2 to 2.3, and
refractive index of the second insulating film is no more than 1.9.

6. The semiconductor laser according to claim 5, wherein the first insulating film is AlN or SiN.

7. The semiconductor laser according to claim 5, wherein the second insulating film is Al₂O₃ or SiO₂.
